(19) United States
(12) Patent Application Publication
(10) Pub. No.: US 2015/0300693 A1
(43) Pub. Date: Oct. 22, 2015

(54) Heat Storage Tank Used In Solar Heat Power System, Solar Heat Dynamo Used Therein And Solar Heat Power System Including The Same

(71) Applicant: Youngbae SONG, (US)

(72) Inventor: Youngbae Song, (US)

(21) Appl. No.: 14/437,539

(22) PCT Filed: Dec. 26, 2013
(86) PCT No.: PCT/KR2013/012184

§ 371 Date: Apr. 22, 2015

(30) Foreign Application Priority Data
Dec. 28, 2012 (KR) 10-2012-0155989

(51) Int. Cl. F24J 2/34; H01L 35/28

(52) U.S. Cl. CPC F24J 2/34; H01L 35/28

(57) ABSTRACT

Disclosed herein are a heat storage tank used in a solar heat power system, including: a housing having a watertight structure; a heat energy storage material filled in the housing and storing heat from an external heat collector; and a solar heat dynamo including a thermoelectric element attached to a side of the housing, and a solar heat dynamo used therein and a solar heat power system including the same.

### CROSS REFERENCE TO RELATED APPLICATION

This application claims the benefit of Korean Patent Application No. 10-2012-0, filed on 2012, entitled “Heat Storage Tank Used in Solar Heat Power System, Solar Heat Dynamo Used Therein and Solar Heat Power System Including the Same”, which is hereby incorporated by reference in its entirety into this application.

### BACKGROUND

1. Technical Field

The present invention relates to a heat storage tank used in a solar heat power system, a solar heat dynamo used therein, and a solar heat power system including the same.

2. Description of the Related Art

An example of the related arts relating to a system using both solar heat and sunlight may include a technology described in Patent Document 1. Patent Document 1 discloses a system that includes a hybrid solar heat collector performing photovoltaic power generation and solar heat collection, a high temperature heat storage tank and a low temperature heat storage tank, and a heat pump using the low temperature heat storage tank as a low temperature side heat source to increase temperature within the high temperature heat storage tank and feeds hot water using the heat pump as a heat source.

Patent Document: In case of a solar heat power system disclosed in JP Patent Laid-Open Publication No. H7-234020, there is a need to rapidly absorb heat and keep the heat for a long period of time so as to effectively use new renewable energy, such as solar heat, and the like, of which the energy supply greatly varies over time due to the imbalance between supply and demand of energy.

When the heat storage tank uses only water as a heat energy storage material, it is difficult to store heat of 100° C. or higher, pressure is increased, heat conduction is slow due to generation of vapor, and a heat storage material is lost, such that the overall power generation efficiency may be reduced.

### SUMMARY OF THE INVENTION

An object of the present invention is to provide a solar heat dynamo capable of minimizing heat loss in a heat storage tank stored from solar heat to increase heating and hot water feeding efficiency and directly performing power generation using heat in a heat storage tank, a heat storage tank used therein, and a solar heat power system including the same.

According to an exemplary embodiment of the present invention, there is provided a heat storage tank used in a solar heat power system, including: a housing having a watertight structure; a heat energy storage material filled in the housing and storing heat from an external heat collector; and a solar heat dynamo including a thermoelectric element attached to a side of the housing.

The solar heat dynamo may have a metal plate that is disposed at one side of the housing and have one surface contacting the heat energy storage material and the other surface attached with the thermoelectric element.

The solar heat dynamo may further include a plurality of heat transfer members that are attached to one surface of the metal plate.

The solar heat dynamo may include a cooler that is disposed on one side of the thermoelectric element to cool the thermoelectric element.

The cooler may include a cooling fin.

The heat storage tank may further include: a cooling fan providing a flow of air in the cooling fin.

The cooler may include a cooling plate attached to one side of the thermoelectric element and having a cooling tube disposed therein, wherein the cooling tube has a cooling liquid flowing therethrough.

The heat energy storage material may be sodium nitrate, potassium nitrate, lithium nitrate, magnesium nitrate hexahydrate, and a mixture thereof or a material kept in a solid or slurry state at normal temperature by injecting water thereinto.

The heat energy storage material may be converted into a liquid phase at 110 to 130° C.

The thermoelectric element may be configured of a thermoelectric cell having a matrix form.

The housing may further include a barrier rib that partitions a first space and a second space, the first space may be used as a heat storage tank for a power generation and heating system, and the second space may be used as a warm water tank.

The first space may be provided with a double heat exchanger.

The double heat exchanger may include a first heat exchange unit transferring heat from the heat collector to the heat energy storage material of the first space; and a second heat exchange unit disposed at an outside of the same axis of the first heat exchange unit to heat a heat transfer medium introduced from the outside.

The heat storage tank may further include: a first sensor measuring temperature of the first space; and a control unit closing a valve of a first supply tube supplying heat to the first space when the temperature measured by the first sensor is lower than that of the heat energy storage material supplied from the heat collector.

The heat storage tank may further include: a second sensor measuring temperature of the second space; a control unit closing a valve of a second supply tube supplying heat to the second space when the temperature measured by the second sensor is lower than that of the heat energy storage material supplied from the heat collector.

According to another exemplary embodiment of the present invention, there is provided a solar heat dynamo attached to a heat storage tank of a solar heat power system, including: a metal plate having one surface contacting a liquid-phase heat energy storage material; a thermoelectric element attached to the other surface of the metal plate; a cooler attached to one surface of the thermoelectric element to cool the thermoelectric element.

The solar heat dynamo may further include: a plurality of heat transfer members attached to one surface of the metal plate and dipped in the liquid-phase heat energy storage material.

The cooler may include a cooling fin.

The cooler may further include a cooling fan providing a flow of air in the cooling fin.

The cooler may include a cooling plate attached to one side of the thermoelectric element and having a cooling tube disposed therein, wherein the cooling tube has a cooling liquid flowing therethrough.

According to still another exemplary embodiment of the present invention, there is provided a heat energy storage material used in a solar heat power system, wherein the heat energy storage material is a mixture of sodium nitrate, potassium nitrate, lithium nitrate, magnesium nitrate hexahydrate or a material kept in a solid or slurry state at normal temperature by injecting water thereinto.

The heat energy storage material may be converted into a liquid phase at 110 to 130° C.

### BRIEF DESCRIPTION OF THE DRAWINGS

FIG. 1 is a schematic diagram of a solar heat power system according to an exemplary embodiment of the present invention.

FIG. 2 is a cross-sectional view of a heat storage tank used in a solar heat power system according to a first exemplary embodiment of the present invention.

FIG. 3 is a cross-sectional view of a heat storage tank used in a solar heat power system according to a second exemplary embodiment of the present invention.

FIG. 4 is a perspective view of an example of a solar heat dynamo used in the heat storage tank of the solar heat power system according to the exemplary embodiment of the present invention.

FIG. 5 is a block configuration diagram of the solar heat power system according to the exemplary embodiment of the present invention.

### DETAILED DESCRIPTION OF THE PREFERRED EMBODIMENTS

Hereinafter, a heat storage tank used in a solar heat power system according to an exemplary embodiment of the present invention, a solar heat dynamo used therein, and a solar heat power system including the same will be described in more detail with reference to the accompanying drawings.

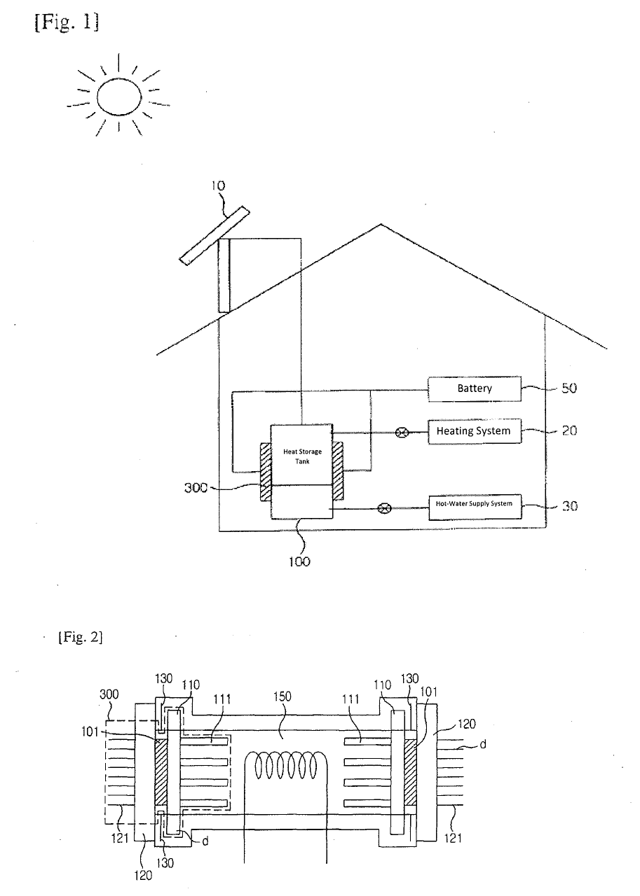

FIG. 1 is a schematic diagram of a solar heat power system according to an exemplary embodiment of the present invention. As illustrated, the solar heat power system according to the exemplary embodiment of the present invention may be used in home, an office building, and the like. The solar heat power system may be configured to include a heat collector 10, a heat storage tank 100, a heating system 20, a hot water feeding system 30, a solar heat dynamo 300, and a battery 50.

The heat collector 10 is disposed in an outdoor area to collect solar heat. The collected heat is transferred to the heat storage tank 100. In case of the solar heat collector, solar heat is generally collected to 150 to 250° C. and heat is transferred to a heat energy storaging material of the heat storage tank.

The heat storage tank 100 is a component of storing heat collected in the heat collector 10. The heat storage tank 100 is configured to include a heat storaging unit that stores solar heat power generation and heat energy for heating and a warm water unit that stores heat energy for feeding warm water. The heat storage tank 100 is provided with a heat exchanger to supply heat energy to the heating system 20 and the hot water feeding system 30. That is, the supply of warm water is made by converting cold water into warm water while passing through the warm water unit of the heat storage tank 100 and the warm water is used to feed hot water. Further, the warm water preheated in the warm water unit is heated by a heat exchanger for heating installed in the heat storaging unit, and thus is used for heating.

In addition, one side of the heat storage tank 100 may be provided with a solar heat dynamo 300 including a thermoelectric element 101 (see FIG. 2). The heat of the heat storage tank 100 is supplied to the thermoelectric element 101 of the solar heat dynamo 300 and is converted into electric energy in the thermoelectric element 101 to generate electric energy, such that the generated electric energy may be transferred to a public power network or stored in the battery 50. The electric energy of the charged battery 50 may be used as power for a home or a building.

As described above, power can be generated at all times in the daytime and even in the nighttime at which solar heat energy is not supplied and the solar heat power generation can be made and warm water for heating and feeding hot water can be simultaneously supplied, by using the high temperature heat energy stored in the heat storage tank, such that the use efficiency of solar heat energy can be increased.

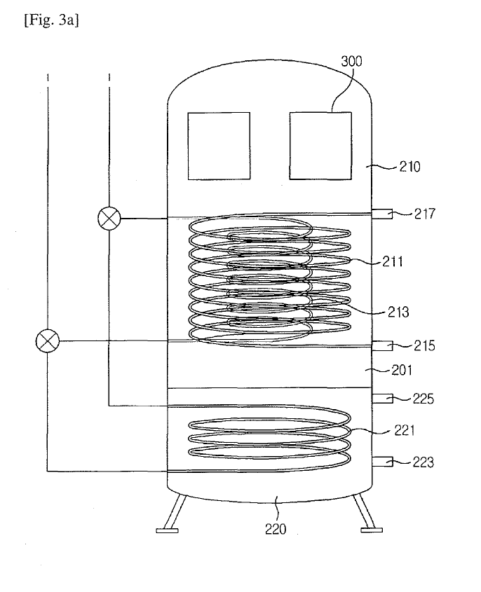

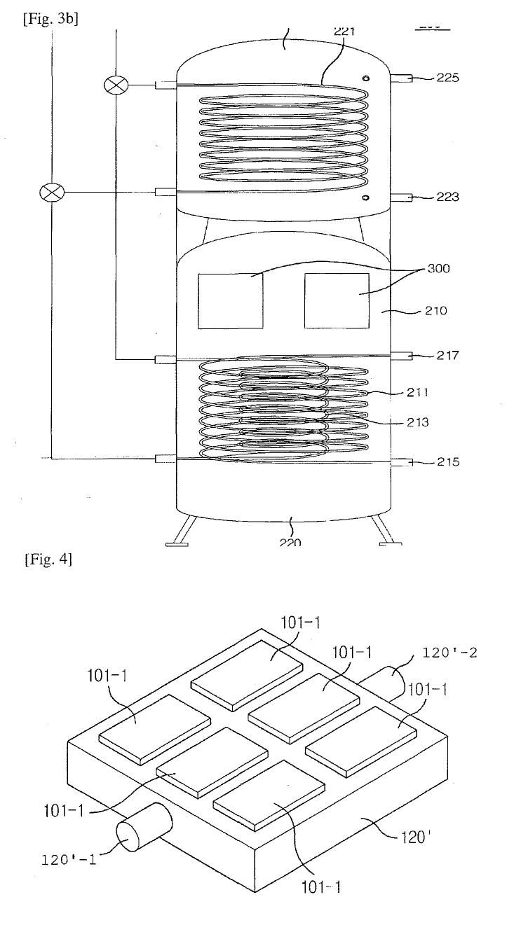

Hereinafter, the configuration of the heat storage tank 100 and the solar heat dynamo 300 that are used in the solar heat power system according to the embodiment of the present invention will be described in more detail with reference to FIGS. 2 and 3.

FIG. 2 is a cross-sectional view of a heat storage tank used in a solar heat power system according to a first exemplary embodiment of the present invention and FIG. 3 is a cross-sectional view of a heat storage tank used in a solar heat power system according to a second exemplary embodiment of the present invention.

As illustrated in FIG. 2, the heat storage tank 100 according to the exemplary embodiment of the present invention may be configured to include a housing, the solar heat dynamo 300 that is disposed at the right and left of the housing to form a closed space, and a heat energy storage material filled in the closed space.

In this configuration, the housing has a watertight structure due to a metal plate 110 and a sealing portion 130 that are components of the dynamo 300 and a space formed in the housing is filled with the heat energy storage material. The heat energy storage material may be a material that is held in a solid or slurry state at normal temperature by injecting water into at least one of sodium nitrate, potassium nitrate, lithium nitrate, magnesium nitrate hexahydrate, and a mixture thereof. In particular, in the present invention, the lithium nitrate and the magnesium nitrate hexahydrate are mixed with each other, such that the heat energy storage material may be converted into a liquid phase at 110 to 130° C. As described above, in the case of the solar heat collector, the solar heat is collected to 150 to 250° C. and the heat energy storage material according to the embodiment of the present invention has a melting point of 110 to 130° C., such that the heat energy can be optimally stored by the phase change of the heat energy storage material.

The solar heat dynamo 300 is a component that converts the stored heat energy into electric energy by the heat energy storage material and may include the metal plate 110 having one surface directly contacting a liquid-phase material, the thermoelectric element 101 attached on the other surface of the metal plate 110, and a cooler 120 disposed on the other side of the thermoelectric element 101, in which the cooler 120 may include a cooling fin 121 for improving performance of the cooler 120.

The metal plate 110 may be formed of a copper plate having high heat conductivity and a heat transfer fin or a heat transfer tube 111 and may be attached with the heat transfer fin or the heat transfer tube 111 that is a heat transfer member for effectively transferring the heat of the heat energy storage material to the thermoelectric element 101. The heat transfer tube 111 is configured of the metal tube and a liquid-phase heat transfer material filled therein and may maximize a heat transfer effect that transfers the heat stored by the heat energy storage material to the metal plate 110.

The cooler 120 serves to cool the other surface of the thermoelectric element 101. As illustrated in FIG. 2, the cooler 120 includes the cooling fin 121 and may cool the other surface of the thermoelectric element 101 by a natural air flow (air cooling type) through the cooling fin 121. Alternatively, the other surface of the thermoelectric element 101 may be cooled by a cooling plate 120′ having cooling water flowing therein. The cooling plate 120′ will be described with reference to FIG. 4.

Meanwhile, the thermoelectric element 101 may be configured of a thermoelectric cell having a matrix form as illustrated in FIG. 4. The thermoelectric element 101 may be configured of a Peltier element. The Peltier element is an element that generates a Peltier phenomenon. The term “Peltier phenomenon” is a phenomenon in which when two types of conductors are coupled to flow current in the conductors, one contact generates heat to increase temperature and the other contact absorbs heat to decreases temperature. When being operated inversely thereto, one contact generates heat and the other contact is cooled, such that current is generated.

In addition, the inside of the housing is provided with a heat exchange unit 150 to transfer the photovoltaic energy collected by the heat collector 10 to the heat energy storage material.

According to the embodiment of the present invention, one side of the thermoelectric element is heated by heat from the heat transfer fin 111 and the other side of the thermoelectric element is cooled by the cooler 120, such that the power generation efficiency may be increased.

Hereinafter, a second exemplary embodiment of the heat storage tank used in the solar heat power system according to the exemplary embodiment of the present invention will be described in more detail with reference to FIG. 3.

FIG. 3 is a cross-sectional view of a heat storage tank used in a solar heat power system according to a second exemplary embodiment of the present invention. As illustrated in FIG. 3, in the second exemplary embodiment 200, two spaces are partitioned by a barrier rib and a first space 210 is used as a heat storage tank for the power generation and heating system and a second space 220 may be used as a warm water tank for the solar heat power generation and hot water feeding system.

As illustrated in FIG. 3, the upper surface of the second exemplary embodiment is attached with the solar heat dynamo 300 to use heat energy from the heat energy storage material filled in the first space 210, thereby generating power. Further, the first space 210 is provided with double heat exchangers 211 and 213. The double heat exchangers 211 and 213 may be configured to include a first heat exchange unit 211 for supplying the heat from the heat collector 10 to the heat energy storage material filled in the first space 210 and a second heat exchange unit 213 disposed at the outside of the first heat exchange unit 211 to heat the warm water of the heating system. 20. That is, the warm water supplied from the heating system 20 is introduced into the first heat exchange unit 211 through a warm water inlet 215 and is heated with the heat energy storage material, and is further heated and supplied to the heating system 20 through a warm water outlet 217.

The second space 220 is used as the warm water tank of the hot water feeding system 30. Herein, the heat supplied from the heat collector 10 is supplied to the hot water feeding heat exchange unit 221 to heat cold water supplied through the cold water inlet 223 and the heated cold water is supplied to the hot water feeding system 30 through a water feeding outlet 225.

Hereinafter, a structure of the solar heat dynamo used in the heat storage tank used in the solar heat power system having the foregoing structure will be described with reference to FIG. 4.

FIG. 4 is a perspective view of an example of the solar heat dynamo used in the heat storage tank of the solar heat power system according to the exemplary embodiment of the present invention. FIG. 4 illustrates an example in which the cooling plate 120′ as the cooler cooling one side of the thermoelectric element is applied. As illustrated in FIG. 4, the thermoelectric element configured of a thermoelectric cell 101-1 having a matrix form is disposed on the cooling plate. The cooling plate 120′ has a zigzag-shaped waterway disposed therein and the cooling water cools one side of the thermoelectric element 101 while being input through an inlet 120′-1 and passing through the waterway and then is discharged to an outlet 120′-2. During this, the other side of the thermoelectric element contacts the metal plate 110 that contacts the heat energy storage material, and therefore is heated. The power generation is made by the temperature difference.

FIG. 4 illustrates an example in which a water cooling method is applied, but the present invention is not limited thereto, and therefore it is to be understood that the air cooling type in which the cooling fan attached generates a flow of air in the cooling fin (see FIG. 2) to perform cooling may also be applied.

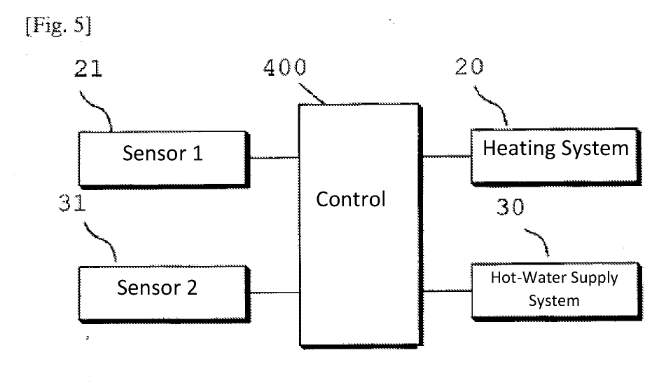

Hereinafter, an electronic configuration of the solar heat power system according to the exemplary embodiment of the present invention will be described in more detail with reference to FIG. 5. It is to be understood that the block configuration diagram of FIG. 5 may be used in the case in which the second exemplary embodiment of FIG. 3 is applied. FIG. 5 is a block configuration diagram of the solar heat power system according to the exemplary embodiment of the present invention. As illustrated in FIG. 5, the solar heat power system according to the exemplary embodiment of the present invention may include a first sensor 21 for measuring temperature of the first space 210, a second sensor 31 for measuring temperature of the second space 220, the heating system 20 using heat transferred by the double heat exchanger disposed in the first space 210, and the hot water feeding system 30 using heat transferred by the hot water feeding heat exchange unit disposed in the second space 220, and a control unit 400.

When the heat supplied from the heat collector 10 is lower than the temperature of the heat storage tank, the heat of the heat storage tanks 100 and 200 is rather deprived by the heat collector 10. In order to prevent this, the first space 210 and the second space 220 are provided with temperature sensors and when the temperature measured by the temperature sensors is lower than that of the heat supplied from the heat collector, the temperature sensors perform a control to stop the supply of heat.

According to the exemplary embodiments of the present invention having the foregoing configuration, it is possible to increase the power generation efficiency by adding the function of directly converting the heat energy collected in the heat storage tank into power by using the thermoelectric element.

Further, according to the exemplary embodiments of the present invention having the foregoing configuration, it is possible to increase the power generation efficiency of the solar heat power system by providing the heat storaging material capable of keeping the absorbed heat for a long period of time while making the heat conduction excellent.

The heat storage tank used in the solar heat power system as described above, the solar heat dynamo used therein, and the solar heat power system including the same may not be limited to the configurations and methods of the foregoing exemplary embodiments, but all or a part of the exemplary embodiments may be selectively combined so as to be variously changed.

### DRAWINGS

### FIG. 1

100: Heat Storage Tank
50: Battery
20: Heating System
30: Hot Water Feeding System

### FIG. 5

21: First Sensor
31: Second Sensor
400: Control Unit
20: Heating System
30: Hot Water Feeding System

What is claimed is:

1. A heat storage tank used in a solar heat power system, comprising:
a housing having a watertight structure;
a heat energy storage material filled in the housing and storing heat from an external heat collector; and
a solar heat dynamo including a thermoelectric element attached to a side of the housing.

2. The heat storage tank of claim 1, wherein the solar heat dynamo has a metal plate that is disposed at one side of the housing and has one surface contacting the heat energy storage material and the other surface attached with the thermoelectric element.

3. The heat storage tank of claim 2, wherein the solar heat dynamo further includes a plurality of heat transfer members that are attached to one surface of the metal plate.

4. The heat storage tank of claim 1, wherein the solar heat dynamo includes a cooler that is disposed on one side of the thermoelectric element to cool the thermoelectric element.

5. The heat storage tank of claim 4, wherein the cooler includes a cooling fin.

6. The heat storage tank of claim 5, further comprising:
a cooling fan providing a flow of air in the cooling fin.

7. The heat storage tank of claim 5, wherein the cooler includes a cooling plate attached to one side of the thermoelectric element and having a cooling tube disposed therein, the cooling tube having a cooling liquid flowing therethrough.

8. The heat storage tank of claim 1, wherein the heat energy storage material is sodium nitrate, potassium nitrate, lithium nitrate, magnesium nitrate hexahydrate, and a mixture thereof or a material kept in a solid or slurry state at normal temperature by injecting water thereinto.

9. The heat storage tank of claim 8, wherein the heat energy storage material is converted into a liquid phase at 110 to 130° C.

10. The heat storage tank of claim 1, wherein the thermoelectric element is configured of a thermoelectric cell having a matrix form.

11. The heat storage tank of claim 1, wherein the housing further includes a barrier rib that partitions a first space and a second space,
the first space is used as a heat storage tank for a power generation and heating system, and
the second space is used as a warm water tank.

12. The heat storage tank of claim 11, wherein the first space is provided with a double heat exchanger.

13. The heat storage tank of claim 12, wherein the double heat exchanger includes:
a first heat exchange unit transferring heat from the heat collector to the heat energy storage material of the first space; and
a second heat exchange unit disposed at an outside of the same axis of the first heat exchange unit to heat a heat transfer medium introduced from the outside.

14. The heat storage tank of claim 12, further comprising:
a first sensor measuring temperature of the first space; and
a control unit closing a valve of a first supply tube supplying heat to the first space when the temperature measured by the first sensor is lower than that of the heat energy storage material supplied from the heat collector.

15. The heat storage tank of claim 14, further comprising:
a second sensor measuring temperature of the second space; and
a control unit closing a valve of a second supply tube supplying heat to the second space when the temperature measured by the second sensor is lower than that of the heat energy storage material supplied from the heat collector.

16. A solar heat dynamo attached to a heat storage tank of a solar heat power system, comprising:
a metal plate having one surface contacting a liquid-phase heat energy storage material;
a thermoelectric element attached to the other surface of the metal plate; and
a cooler attached to one surface of the thermoelectric element to cool the thermoelectric element.

17. The solar heat dynamo of claim 16, further comprising:
a plurality of heat transfer members attached to one surface of the metal plate and dipped in the liquid-phase heat energy storage material.

18. The solar heat dynamo of claim 16, further comprising:
a cooler disposed on one side of the thermoelectric element to cool the thermoelectric element.

19. The solar heat dynamo of claim 17, wherein the cooler includes a cooling fin.

20. The solar heat dynamo of claim 18, wherein the cooler further includes a cooling fan providing a flow of air in the cooling fin.

21. The solar heat dynamo of claim 18, wherein the cooler includes a cooling plate attached to one side of the thermoelectric element and having a cooling tube disposed therein, the cooling tube having a cooling liquid flowing therethrough.

22. A heat energy storage material used in a solar heat power system, wherein the heat energy storage material is a mixture of sodium nitrate, potassium nitrate, lithium nitrate, magnesium nitrate hexahydrate or a material kept in a solid or slurry state at normal temperature by injecting water thereinto.

23. The heat storage tank of claim 22, wherein the heat energy storage material is converted into a liquid phase at 110 to 130° C.
